(19) United States
(12) Patent Application Publication
(10) Pub. No.: US 2012/0181065 A1
(43) Pub. Date: Jul. 19, 2012

(54) Multi-Layered Circuit Board Device

(75) Inventor: Kuei-Wu Chu, Taoyuan County (TW)

(73) Assignee: MAO BANG ELECTRONIC CO., LTD., Taoyuan County (TW)

(21) Appl. No.: 13/160,928

(22) Filed: Jun. 15, 2011

(30) Foreign Application Priority Data
Jan. 13, 2011 (TW) 100200760

(51) Int. Cl. H05K 1/09

(52) U.S. Cl. 174/251

(57) ABSTRACT

A multi-layered circuit board device includes an isolative layer and a wiring layer sequentially provided on a circuit board in a PCB, ceramic, LTCC or aluminum nitride build-up process. Thus, the thickness of the multi-layered circuit board device is small and the density of the multi-layered the circuit board device is high. Furthermore, the structure of the multi-layered circuit board device is simple and the cost of the multi-layered circuit board device is low. The layers are connected to one another in the PCB, ceramic, LTCC or aluminum nitride build-up process without having to use additional alignment target points.

### BACKGROUND OF INVENTION

1. Field of Invention

The present invention relates to a multi-layered circuit board device and, more particularly, to a multi-layered circuit board device including an isolative layer and a wiring layer sequentially provided on a circuit board in a PCB, ceramic, LTCC or aluminum nitride build-up process.

2. Related Prior Art

A conventional circuit board includes a substrate made of glass fiber cloth, linen cloth, paper and resin. A conductive layer is provided on the substrate by electroplating or copper-piling. Finally, a wiring is made of the conductive layer by etching redundant portions of the conductive layer. Thus, the circuit board is made. Electronic elements can be electrically connected to the wiring formed on the circuit board.

The manufacturing of the circuit board is however complicated. In addition, the thickness of the circuit board is large and the density of the circuit board is low. Hence, the thickness of a semiconductor device that includes the circuit board is large but the density of the semiconductor device is low.

The present invention is therefore intended to obviate or at least alleviate the problems encountered in prior art.

### SUMMARY OF INVENTION

It is an objective of the present invention to provide a structurally simple and inexpensive multi-layered circuit board device with any desired number of layers in a PCB, ceramic, LTCC or aluminum nitride build-up process.

It is another objective of the present invention to provide a multi-layered circuit board device with small thickness and high density.

To achieve the foregoing objectives, the multi-layered circuit board device includes a circuit board, at least one isolative layer provided on the circuit board, and at least one wiring layer provided on the isolative layer. The circuit board includes a substrate, at least two light-sensing isolative layers and at least four conductive layers. The substrate includes apertures defined therein. The first light-sensing isolative layer is provided on substrate. The first conductive layer is provided the substrate and the first light-sensing isolative layer. The first conductive layer is polished. The second conductive layer is provided on the first conductive layer so that the second conductive layer further levels the first conductive layer. The second light-sensing isolative layer is provided on the first and second conductive layers. The third conductive layer is provided on the first conductive layer and the second light-sensing isolative layer. The third conductive layer is polished. The fourth conductive layer is provided on the third conductive layer so that the fourth conductive layer further levels the third conductive layer.

The substrate may be a hard board, a soft board or copper-less substrate.

The apertures may be made in the substrate by mechanical drilling.

The first and second light-sensing isolative layers may be SU8.

The first conductive layer may be provided on the first light-sensing isolative layer by silver-printing or chemical copper-coating.

The third conductive layer may be provided on the first conductive layer and the second light-sensing isolative layer by silver-printing or chemical copper-coating.

The first to fourth conductive layers may be made of silver paste.

The multi-layered circuit board device may further include at least fifth and sixth conductive layers. The fifth conductive layer is provided on the isolative layer. The fifth conductive layer is polished. The sixth conductive layer is provided on the fifth conductive layer so that the sixth conductive layer further levels the fifth conductive layer. The wiring layer is provided on the sixth conductive layer. The fifth and sixth conductive layers may be made of silver paste. The fifth conductive layer is sandwiched between the circuit board and the isolative layer by silver-printing or chemical copper-coating.

The multi-layered circuit board device may further includes at least one third light-sensing isolative layer and at least seventh and eighth conductive layers. The third light-sensing isolative layer is provided on the isolative layer and the wiring layer. The seventh conductive layer is provided on the wiring layer and the third light-sensing isolative layer. The seventh conductive layer is polished. The eighth conductive layer is provided on the seventh conductive layer so that the eighth conductive layer further levels the seventh conductive layer. The third light-sensing isolative layer may be SUB. The seventh and eight conductive layers may be made of silver paste. The seventh conductive layer may be provided on the isolative layer and the third light-sensing isolative layer by silver-printing or chemical copper-coating.

Other objectives, advantages and features of the present invention will be apparent from the following description referring to the attached drawings.

### BRIEF DESCRIPTION OF DRAWINGS

The present invention will be described via detailed illustration of three embodiments referring to the drawings wherein:

FIG. 1 is a cross-sectional view of a circuit board device according to the first embodiment of the present invention;

FIG. 2 is a cross-sectional view of a circuit board device according to the second embodiment of the present invention; and

FIG. 3 is a cross-sectional view of a circuit board device according to the third embodiment of the present invention.

### DETAILED DESCRIPTION OF EMBODIMENTS

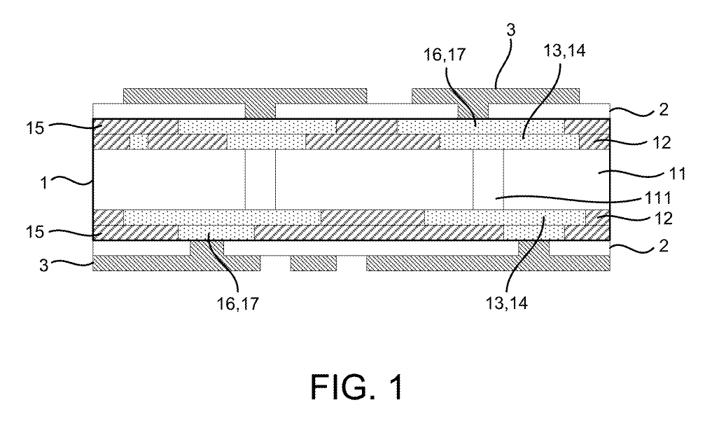

Referring to FIG. 1, there is shown a circuit board device according to a first embodiment of the present invention. The circuit board device includes a circuit board 1, two isolative layers 2 and two wiring layers 3.

The circuit board 1 includes a substrate 11, two first light-sensing isolative layers 12, two first conductive layers 13, two second conductive layers 14, two second light-sensing isolative layers 15, two third conductive layers 16 and two fourth conductive layers 17. The substrate 11 may be a hard board, a soft board or a copper-less substrate. The substrate 11 may be used in a printed circuit board (“PCB”), a ceramic substrate, a low temperature co-fired ceramic (“LTCC”) substrate or an aluminum nitride substrate. The substrate 11 includes apertures 111 defined therein.

The first light-sensing isolative layers 12 may be SU8. A first side of each of the first light-sensing isolative layers 12 is provided on a related one of two opposite sides of the substrate 11.

A first side of each of the first conductive layers 13 is provided on a second side of a related one of the first light-sensing isolative layers 12 and a related one of the sides of the substrate 11. Polished is a second side of each of the first conductive layers 13.

A first side of each of the second conductive layers 14 is provided on the second side of a related one of the first conductive layers 13. Thus, the second conductive layers 14 further level the first conductive layers 13.

The second light-sensing isolative layers 15 may be SU8. A first side of each of the second light-sensing isolative layers 15 is provided on a second side of a related one of the second conductive layers 14, which further levels the second side of a related one of the first conductive layers 13.

A first side of each of the third conductive layers 16 is provided on a second side of a related one of the second light-sensing isolative layers 15 and the second side of a related one of the second conductive layers 14, which further levels the second side of a related one of the first conductive layers 13. Polished is a second side of each of the third conductive layer 16, which covers a related one of the second light-sensing isolative layer 15.

A first side of each of the fourth conductive layers 17 is provided on the second side of a related one of the third conductive layers 16. Thus, the fourth conductive layers 17 further level the third conductive layers 16. The first to fourth conductive layers may be made of silver paste.

A first side of each of the isolative layers 2 is provided on a second side of a related one of the fourth conductive layers 17 of the circuit board 1. Each of the isolative layers 2 may be a PCB, a ceramic layer, an LTCC layer or an aluminum nitride layer.

A first side of each of the wiring layers 3 is provided on a second side of a related one of the isolative layers 2. Each of the wiring layers 3 may be a PCB, a ceramic layer, LTCC layer or an aluminum nitride layer. Now, the multi-layered circuit board device is finished.

To make the multi-layered circuit board device, the apertures 111 are made on the substrate 11 by mechanical drilling. Then, the first light-sensing isolative layers 12 are provided on the opposite sides of the substrate 11. The first conductive layers 13 are provided on the first light-sensing isolative layers 12 and the substrate 11 before the second sides thereof are polished. The second conductive layers 14 are provided on the first conductive layers 13 so that the second conductive layers 14 cover defects made on the first conductive layers 13 during the making of the circuit board device. That is, the second conductive layers 14 further level the first conductive layers 13. Then, the second light-sensing isolative layers 15 are provided on the second conductive layers 14, which further level the first conductive layers 13. By silver-printing or chemical copper-coating, the third conductive layers 16 are provided on the second light-sensing isolative layers 15 and the second conductive layers 14, which further level the first conductive layers 13 before the second sides thereof are polished. Finally, the fourth conductive layers 17 are provided on the third conductive layers 16 so that the fourth conductive layers 17 cover defects made on the third conductive layers 16 during the manufacturing of the circuit board device. That is, the fourth conductive layers 17 further level the third conductive layers 16.

In a PCB build-up process, the isolative layers 2 and the wiring layers 3 are provided on the circuit board 1 in order. Hence, the thickness of the multi-layered circuit board device is small while the density of the multi-layered circuit board device is high. The multi-layered circuit board device can be made with any desired number of layers because of the PCB build-up process and the structure of the circuit board 1 without having to use alignment target points. In the PCB build-up process, the apertures or wires are used for alignment of the layers with one another. The connection of the layers to one another is done in a PCB, ceramic, LTCC or aluminum nitride build-up process.

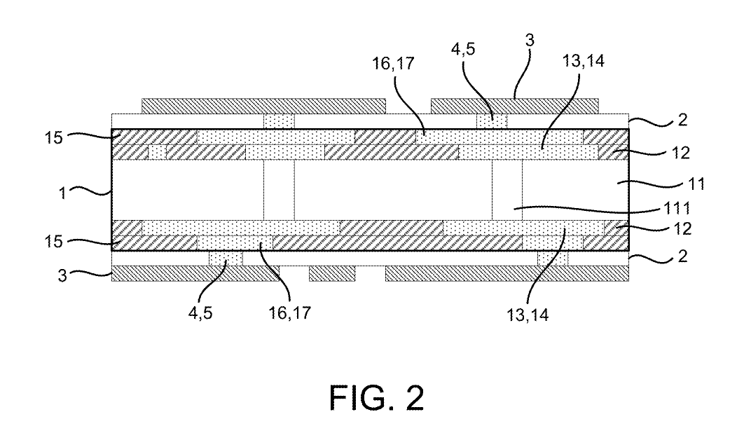

Referring to FIG. 2, there is shown a circuit board device according to a second embodiment of the present invention. The second embodiment is like the first embodiment except including a fifth conductive layer 4 and a sixth conductive layer 5 between each of the isolative layers 2 and a related one of the wiring layers 3. Each of the fifth conductive layers 4 is provided on a related one of the isolative layers 2 and a related one of the opposite sides of the circuit board 1 by silver-printing or chemical copper-coating. The fifth conductive layers 4, which are provided on the isolative layers 2, are polished. Each of the sixth conductive layers 5 is coated on a related one of the fifth conductive layers 4 so that the sixth conductive layers 5 cover defects that occur on the fifth conductive layers 4 during the making of circuit board device, i.e., the sixth conductive layers 5 further level the fifth conductive layers 4. Finally, the wiring layers 3 are provided on the fifth conductive layers 4, which further level the isolative layers 2. The connection of the layers to one another is done in a PCB, ceramic, LTCC or aluminum nitride build-up process.

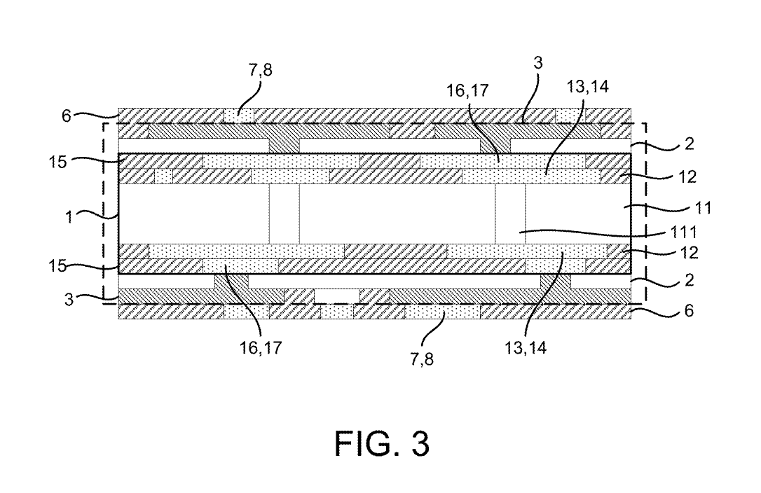

Referring to FIG. 3, there is shown a circuit board device according to a third embodiment of the present invention. The third embodiment is like the first embodiment except including a third-sensing isolative layer 6, a seventh conductive layer 7 and an eight conductive layer 8 provided on each of the isolative layers 2 and a related one of the wiring layers 3. The third light-sensing isolative layers 6 may be SU8. The third light-sensing isolative layers 6 are provided on the wiring layers 2 and the wiring layers 3 by silver-printing or chemical copper-coating. The seventh conductive layers 7 are provided on the third light-sensing isolative layers 6 by silver-printing or chemical copper-coating. The seventh conductive layers 7 are polished. Then, the eighth conductive layers 8 are provided on the seventh conductive layers 7 so that the eighth conductive layers 8 cover defects that occur on the seventh conductive layers 7, i.e., the eighth conductive layers 8 further level the seventh conductive layers 7. The connection of the layers to one another is done in a PCB, ceramic, LTCC or aluminum nitride build-up process.

As discussed above, the isolative layer 2 and the wiring layer 3 are sequentially provided on the circuit board 1 the PCB, Ceramic, LTCC or aluminum nitride build-up process. Hence, the thickness of the multi-layered circuit board device is small and the density of the multi-layered circuit board device is high. Furthermore, the multi-layered circuit board device can be made with any desired number of layers because of the structure thereof and the PCB, ceramic, LTCC or aluminum nitride build-up process. Moreover, the structure of the multi-layered circuit board device is simple and the cost of the multi-layered circuit board device is low. Furthermore, the layers are connected to one another in the PCB, ceramic, LTCC or aluminum nitride build-up process without having to use additional target points.

The present invention has been described via the detailed illustration of the embodiments. Those skilled in the art can derive variations from the embodiments without departing from the scope of the present invention. Therefore, the embodiments shall not limit the scope of the present invention defined in the claims.

1. A multi-layered circuit board device including:
a circuit board including:
a substrate 11 including apertures 111 defined therein;
at least one first light-sensing isolative layer 12 provided on substrate 11;
at least one first conductive layer 13 provided the substrate 11 and the first light-sensing isolative layer 12, wherein the first conductive layer 13 is polished;
at least one second conductive layer 14 provided on the first conductive layer 13 so that the second conductive layer 14 further levels the first conductive layer 13;
at least one second light-sensing isolative layer 15 provided on the first and second conductive layers 13, 14;
at least one third conductive layer 16 provided on the first conductive layer 13 and the second light-sensing isolative layer 15, wherein the third conductive layer 16 is polished; and
at least one fourth conductive layer 17 provided on the third conductive layer 16 so that the fourth conductive layer 17 further levels the third conductive layer 16;
at least one isolative layer 2 provided on the circuit board 1; and
at least one wiring layer 3 provided on the isolative layer 2.

2. The multi-layered circuit board device according to claim 1, wherein the substrate 11 is selected from the group consisting of a hard board, a soft board and copper-less substrate.

3. The multi-layered circuit board device according to claim 1, wherein the apertures 111 are made in the substrate 11 by mechanical drilling.

4. The multi-layered circuit board device according to claim 1, wherein the first and second light-sensing isolative layers 12, 15 are SU8.

5. The multi-layered circuit board device according to claim 1, wherein the first conductive layer is provided on the first light-sensing isolative layer by silver-printing.

6. The multi-layered circuit board device according to claim 1, wherein the first conductive layer is provided on the first light-sensing isolative layer by chemical copper-coating.

7. The multi-layered circuit board device according to claim 1, wherein the third conductive layer is provided on the first conductive layer and the second light-sensing isolative layer by silver-printing.

8. The multi-layered circuit board device according to claim 1, wherein the third conductive layer is provided on the first conductive layer and the second light-sensing isolative layer by chemical copper-coating.

9. The multi-layered circuit board device according to claim 1, wherein the first to fourth conductive layers are made of silver paste.

10. The multi-layered circuit board device according to claim 1, further including:
at least one fifth conductive layer 4 provided on the isolative layer 2, wherein the fifth conductive layer is polished; and
at least one sixth conductive layer 5 provided on the fifth conductive layer 4 so that the sixth conductive layer 5 further levels the fifth conductive layer 4, wherein the wiring layer 3 is provided on the sixth conductive layer 5.

11. The multi-layered circuit board device according to claim 10, wherein the fifth and sixth conductive layers are made of silver paste.

12. The multi-layered circuit board device according to claim 10, wherein the fifth conductive layer is sandwiched between the circuit board and the isolative layer by silver-printing.

13. The multi-layered circuit board device according to claim 10, wherein the fifth conductive layer is provided on the circuit board and the isolative layer by chemical copper-coating.

14. The multi-layered circuit board device according to claim 1, further including:
at least one third light-sensing isolative layer provided on the isolative layer and the wiring layer;
at least one seventh conductive layer provided on the wiring layer and the third light-sensing isolative layer, wherein seventh conductive layer is polished; and
at least one eighth conductive layer provided on the seventh conductive layer so that the eighth conductive layer further levels the seventh conductive layer.

15. The multi-layered circuit board device according to claim 14, wherein the third light-sensing isolative layer is SU8.

16. The multi-layered circuit board device according to claim 14, wherein the seventh and eight conductive layers are made of silver paste.

17. The multi-layered circuit board device according to claim 14, wherein the seventh conductive layer is provided on the isolative layer and the third light-sensing isolative layer by silver-printing.

18. The multi-layered circuit board device according to claim 14, wherein seventh conductive layer is provided on the isolative layer and the third light-sensing isolative layer by chemical copper-coating.
